(19) United States
(12) Patent Application Publication
(10) Pub. No.: US 2025/0287815 A1
(43) Pub. Date: Sep. 11, 2025

(54) DISPLAY DEVICE

(71) Applicant: Samsung Display Co., LTD., Yongin-si, Gyeonggi-do (KR)

(72) Inventors: DOGI LIM, Yongin-si (KR); JIYOUNG BANG, Yongin-si (KR); JAESUN LEE, Yongin-si (KR); DOOYOUNG JUNG, Yongin-si (KR)

(21) Appl. No.: 18/968,484

(22) Filed: Dec. 4, 2024

(30) Foreign Application Priority Data
Mar. 5, 2024 (KR) 10-2024-0031170

(51) Int. Cl. H10K 59/80; H10K 59/126; H10K 59/131

(52) U.S. Cl. CPC H10K 59/873; H10K 59/126; H10K 59/131

(57) ABSTRACT

A display device includes a display panel and a gate driving circuit. The display panel includes a base layer including a display area and a non-display area, driving lines disposed on the base layer, connected to the gate driving circuit, and extending in a first direction, an upper insulating layer disposed on the base layer, a first dam disposed on the upper insulating layer and overlapping the non-display area, a second dam spaced farther apart from the display area than the first dam, and a shielding portion disposed between the first and second dams. The shielding portion includes a first portion overlapping at least one of the driving lines and extending in a second direction, and second-first and second-second portions that are respectively protruded from one end and the other end of the first portion in the first direction and that do not overlap the driving lines.

This application claims priority to Korean Patent Application No. 10-2024-0031170, filed on Mar. 5, 2024, and all the benefits accruing therefrom under 35 U.S.C. § 119, the content of which in its entirety is herein incorporated by reference.

### BACKGROUND

### 1. Field

The invention relates to a display device, and more particularly to a display device including a shielding portion to prevent an organic material from overflowing in a process of forming an encapsulation layer.

### 2. Description of Related Art

Various display devices with application to multimedia devices, such as televisions, mobile phones, tablet computers, navigation devices, and game devices, are being developed.

When moisture or oxygen permeates a light emitting element of a display device, the reliability of the display device decreases. Accordingly, an encapsulation layer covering the light emitting element is formed to prevent the moisture or oxygen from permeating into the light emitting element.

However, a portion of an organic material for an organic layer included in the encapsulation layer overflows into a non-display area of the display device in a process of forming the organic layer included in the encapsulation layer.

### SUMMARY

The invention provides a display device capable of preventing an organic material for an organic layer from overflowing into a non-display area through a capillary phenomenon in a process of forming the organic layer included in an encapsulation layer.

Embodiments of the invention provide a display device including a display panel including pixels and a gate driving circuit which outputs a signal to the display panel.

In an embodiment, the display panel includes a base layer including a display area and a non-display area disposed adjacent to the display area, driving lines disposed on the base layer, connected to the gate driving circuit, and extending in a first direction, an upper insulating layer disposed on the base layer, a first dam disposed on the upper insulating layer and overlapping the non-display area, a second dam disposed on the upper insulating layer and spaced farther apart from the display area than the first dam is, and a shielding portion disposed between the first dam and the second dam on the upper insulating layer.

In an embodiment, the shielding portion includes a first portion overlapping at least one of the driving lines and extending in a second direction intersecting the first direction, a second-first portion that is protruding from one end of the first portion in the first direction and that does not overlap the driving lines, and a second-second portion that is protruding from the other end of the first portion in the first direction and that does not overlap the driving lines.

In an embodiment, the shielding portion is provided in plural, and the shielding portions are arranged to be spaced apart from each other in the second direction.

In an embodiment, at least a portion of the shielding portions further include a third portion that is disposed between the second-first portion and the second-second portion, that protrudes from the first portion in the first direction, and that does not overlap the driving lines.

In an embodiment, the third portion includes a third-first portion having a first width in the second direction and a third-second portion having a second width in the second direction.

In an embodiment, the first width is different from the second width.

In an embodiment, the display panel further includes a lower insulating layer disposed between the base layer and the driving lines and an intermediate insulating layer disposed between the lower insulating layer and the upper insulating layer and covering the driving lines. The upper insulating layer is disposed on the intermediate insulating layer, and a stepped portion is defined between an upper surface of the lower insulating layer and a side surface of each of the driving lines due to a thickness of the driving lines.

In an embodiment, an intermediate curved portion curved corresponding to a shape of the stepped portion is defined in the intermediate insulating layer.

In an embodiment, an upper curved portion curved corresponding to a shape of the intermediate insulating layer is defined in the upper insulating layer.

In an embodiment, the display panel further includes an initial dam disposed on the upper insulating layer and disposed closer to the display area than the first dam and an encapsulation layer including a first inorganic layer disposed on the upper insulating layer and covering the shielding portion, an organic layer that is disposed on the first inorganic layer and that does not overlap the shielding portion, and a second inorganic layer disposed on the organic layer and covering the shielding portion.

In an embodiment, a boundary of the organic layer is defined by the initial dam, and wherein an inorganic curved portion curved corresponding to a shape of the upper curved portion is defined in the first inorganic layer.

In an embodiment, the display panel further includes an over-organic material that is disposed on the first inorganic layer and covered by the second inorganic layer, wherein at least a portion of the over-organic material extends in the first direction.

In an embodiment, the over-organic material includes the same material as the organic layer.

In an embodiment, the display panel further includes an organic insulating layer disposed on the upper insulating layer and a pixel definition layer disposed on the organic insulating layer. The shielding portion includes a first shielding layer including the same material as the organic insulating layer and a second shielding layer disposed on the first shielding layer and including the same material as the pixel definition layer.

In an embodiment, the gate driving circuit overlaps the non-display area, and the shielding portion is spaced farther apart from the display area than the gate driving circuit is.

In an embodiment, a first thickness of the second-first portion in a third direction directed perpendicular to the first and second directions is uniform in the second direction in an area overlapping an upper surface of the second-first portion, and a second thickness of the second-second portion in the third direction is uniform in the second direction in an area overlapping an upper surface of the second-second portion.

In an embodiment, the second-first portion is protruding from the first portion in the first direction by a first protrusion length, and the second-second portion is protruding from the first portion in the first direction by a second protrusion length.

In an embodiment, the first protrusion length is equal to the second protrusion length.

In an embodiment, each of the first protrusion length and the second protrusion length is equal to or greater than a value obtained by multiplying a number of the driving lines intersecting the first portion when viewed in a plane by about 1.8 micrometers and equal to or smaller than a value obtained by multiplying the number of the driving lines intersecting the first portion when viewed in the plane by about 2.2 micrometers.

In an embodiment, the shielding portion further includes a first tip portion connected to a surface of the first portion, which faces the first dam, and a surface of the second-first portion, which faces the second-second portion, and a second tip portion connected to the surface of the first portion, which faces the first dam, and a surface of the second-second portion, which faces the second-first portion.

In an embodiment, the first tip portion has a size smaller than a size of the second-first portion when viewed in a plane, and the second tip portion has a size smaller than a size of the second-second portion when viewed in the plane.

In an embodiment, the shielding portion includes a third portion that is disposed between the second-first portion and the second-second portion, that protrudes from the first portion in the first direction, and that does not overlap the driving lines, a third tip portion connected to the surface of the first portion, which faces the first dam, and a surface of the third portion, which faces the second-first portion, and a fourth tip portion connected to the surface of the first portion, which faces the first dam, and a surface of the third portion, which faces the second-second portion

In an embodiment, the third tip portion and the fourth tip portion have a size smaller than a size of the third portion when viewed in a plane.

In an embodiment, the gate driving circuit includes a first gate driving circuit overlapping the non-display area and a second gate driving circuit overlapping the non-display area and spaced apart from the first gate driving circuit with the display area interposed therebetween in the first direction.

Embodiments of the invention provide a display device including a display panel including a base layer including a display area and a non-display area disposed adjacent to the display area, a lower insulating layer disposed on the base layer, driving lines disposed on the lower insulating layer and extending in a first direction, an upper insulating layer disposed on the lower insulating layer, and a first dam, a shielding portion, and a second dam, which are arranged to be spaced apart from each other in a direction directed away from the display area, and a gate driving circuit overlapping the non-display area and disposed closer to the display area than the first dam is.

In an embodiment, the upper insulating layer includes a first upper portion that overlaps the driving lines and a second upper portion that does not overlap the driving lines.

In an embodiment, an upper surface of the first upper portion is spaced apart from an upper surface of the lower insulating layer by a first distance, and an upper surface of the second upper portion is spaced apart from the upper surface of the lower insulating layer by a second distance which is smaller than the first distance.

In an embodiment, the shielding portion includes a first portion overlapping the first and second upper portions, a second-first portion protruding from one end of the first portion toward the display area and overlapping the second upper portion, and a second-second portion protruding from the other end of the first portion toward the display area.

In an embodiment, the shielding portion further includes a third portion disposed between the second-first portion and the second-second portion, protruding from a surface of the first portion, which faces the first dam, to the display area, and overlapping the second upper portion.

In an embodiment, each of a first protrusion length of the second-first portion protruding from the first portion toward the display area and a second protrusion length of the second-second portion protruding from the first portion toward the display area is equal to or greater than a value obtained by multiplying a number of the driving lines overlapping the first portion by about 1.8 micrometers and equal to or smaller than a value obtained by multiplying the number of the driving lines by about 2.2 micrometers.

In an embodiment, the display panel further includes an encapsulation layer including a first inorganic layer disposed on the upper insulating layer, an organic layer disposed on the first inorganic layer, and a second inorganic layer disposed on the organic layer.

In an embodiment, the first inorganic layer includes a first inorganic portion overlapping the first upper portion and a second inorganic portion overlapping the second upper portion.

In an embodiment, the display panel further includes an over-organic material disposed on the first inorganic layer, covered by the second inorganic layer, and including the same material as the organic layer.

In an embodiment, a value obtained by multiplying a separation distance between the second-first portion and the second-second portion, one protrusion length that is smaller than the other protrusion length between the first protrusion length of the second-first portion protruding from the first portion toward the display area and the second protrusion length of the second-second portion protruding from the first portion toward the display panel, and a height of the shielding portion is defined as a volume of a barrier space.

In an embodiment, the volume of the barrier space is equal to or greater than about twelve times and equal to or smaller than about thirty times a volume of the over-organic material disposed between the second-first portion and the second-second portion.

In an embodiment and according to the above, the organic material, which is used for the formation of the organic layer, is prevented from overflowing into the non-display area of the display device in the process of forming the organic layer included in the encapsulation layer of the display device.

### BRIEF DESCRIPTION OF THE DRAWINGS

The above and other advantages of the invention will become readily apparent by reference to the following detailed description when considered in conjunction with the accompanying drawings wherein:

FIG. 1A is a perspective view of a display device, according to an embodiment;

FIG. 1B is an exploded perspective view of a display device, according to an embodiment;

FIG. 2 is a cross-sectional view of a display device, according to an embodiment;

FIG. 3 is a cross-sectional view of a display panel, according to an embodiment;

FIG. 4 is a plan view of a display panel, according to an embodiment;

FIG. 5A is a plan view of a display panel, according to a comparative example;

FIG. 5B is a plan view of a display panel, according to a comparative example;

FIG. 5C is a cross-sectional view of the display panel in FIG. 5B taken along a line I-I′ of FIG. 5B;

FIG. 6 is a plan view of a display panel corresponding to an area AA′ of FIG. 4, according to an embodiment;

FIG. 7 is a perspective view of a shielding portion, according to an embodiment;

FIG. 8A is a cross-sectional view of the display panel taken along a line I-I′ of FIG. 6, according to an embodiment;

FIG. 8B is a cross-sectional view of the display panel taken along a line II-II′ of FIG. 6, according to an embodiment;

FIG. 8C is a cross-sectional view of the display panel corresponding to an area DD′ of FIG. 8B, according to an embodiment;

FIG. 8D is a cross-sectional view of the display panel taken along a line III-III′ of FIG. 6, according to an embodiment;

FIG. 9 is a plan view of a shielding portion, according to an embodiment;

FIG. 10 is a plan view of a shielding portion, according to an embodiment;

FIG. 11 is a plan view of a shielding portion, according to an embodiment;

FIG. 12 is a plan view of a shielding portion, according to an embodiment; and

FIG. 13 is a plan view of a display panel, according to an embodiment.

### DETAILED DESCRIPTION

The invention may be variously modified and realized in many different forms, and thus specific embodiments will be exemplified in the drawings and described in detail hereinbelow. However, the invention should not be limited to the specific disclosed forms, and should be construed to include all modifications, equivalents, or replacements included in the spirit and scope of the invention.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the invention will be described with reference to accompanying drawings.

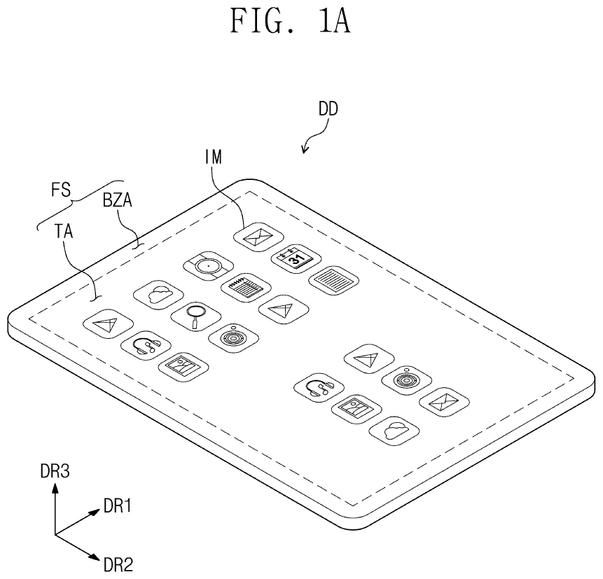

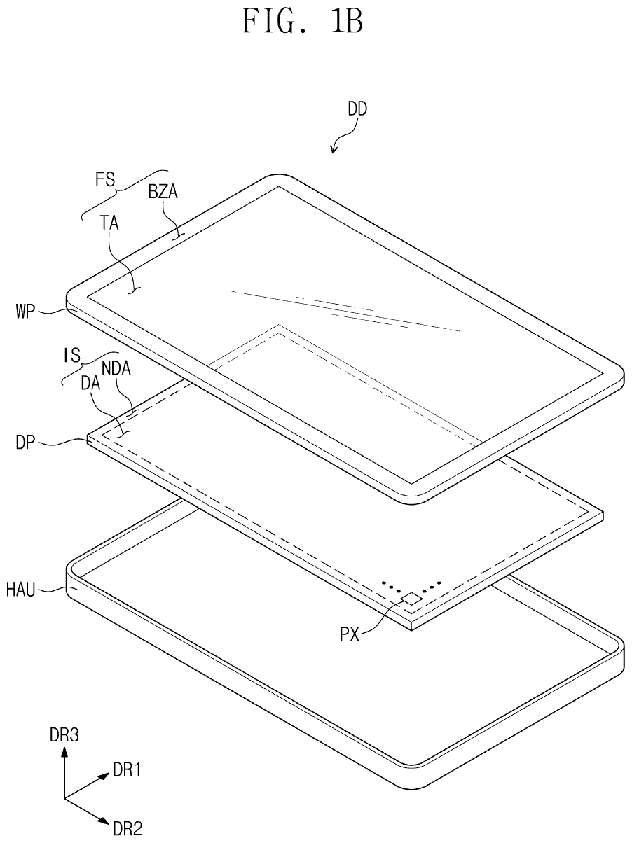

FIG. 1A is a perspective view of a display device DD, according to an embodiment, and FIG. 1B is an exploded perspective view of the display device DD, according to an embodiment.

In an embodiment and referring to FIG. 1A, the display device DD may be activated in response to electrical signals and may display images. The display device DD may be applied to various embodiments to provide various users with the images. As an example, the display device DD may be applied to a large-sized electronic item, such as a television set or an outdoor billboard. In addition, the display device DD may be applied to a small and medium-sized electronic item, such as a monitor, a mobile phone, a tablet computer, a navigation unit, a game unit, etc. The display device DD may be a foldable display device including a folding area and a non-folding area or a bendable display device including at least one bending portion. However, the display device DD should not be limited as long as it does not depart from the invention.

In an embodiment, the display device DD may display an image IM through a display surface FS, which is substantially parallel to a plane defined by a first direction DR1 and a second direction DR2, toward a third direction DR3. The third direction DR3 may be substantially parallel to a normal line direction of the display surface FS.

The display surface FS in which the image IM is displayed may correspond to a front surface of the display device DD and the image IM may include a video and a still image. FIG. 1A shows application icons as a representative example of the image IM.

In an embodiment, front (or upper) and rear (or lower) surfaces of each member or each unit of the display device DD may be defined with respect to a direction in which the image IM is displayed. The front and rear surfaces may be disposed opposite to each other in the third direction DR3, and a normal line direction of each of the front and rear surfaces may be substantially parallel to the third direction DR3. A separation distance between the front and rear surfaces of the member (or the unit) may correspond to a thickness in the third direction DR3 of the member (or the unit).

In the following description, the expression “when viewed in a plane” means a state of being viewed in the third direction DR3. In the following description, the expression “when viewed in a cross-section” means a state of being viewed in the first direction DR1 or the second direction DR2. Meanwhile, directions indicated by the first, second, and third directions DR1, DR2, and DR3, respectively, may be relative to each other and may be changed to other directions.

In an embodiment, the display surface FS of the display device DD through which the image IM is displayed may correspond to a front surface FS (refer to FIG. 1B) of a window WP (refer to FIG. 1B). Accordingly, the display surface and the front surface of the display device DD and the front surface of the window WP will be assigned with the same reference numeral.

In an embodiment and referring to FIG. 1B, the display device DD may include the window WP, a display panel DP, and a housing HAU.

In an embodiment, the front surface FS of the window WP may include a transmissive area TA and a bezel area BZA. A user may view the image IM (refer to FIG. 1A) provided through the transmissive area TA of the window WP.

The transmissive area TA may be an optically transparent area and the bezel area BZA may be an area having a relatively lower transmittance than the transmissive area TA. The bezel area BZA may have a predetermined color and may be disposed adjacent to the transmissive area TA. FIG. 1B shows a structure in which the bezel area BZA surrounds the transmissive area TA. However, the invention should not be limited thereto or thereby, and the bezel area BZA may be disposed adjacent to only one side of the transmissive area TA.

In an embodiment and referring to FIG. 1B, the transmissive area TA may have a quadrangular shape with rounded vertices, however, this is merely an example. In another embodiment, the transmissive area TA may have a variety of shapes and should not be particularly limited.

In an embodiment, the display panel DP may have a configuration that substantially generates the image IM (refer to FIG. 1A), where the image IM generated by the display panel DP may be displayed through a display surface IS, and a user may view the image IM through the transmissive area TA.

The display panel DP may include a display area DA and a non-display area NDA disposed adjacent to the display area DA. The display area DA may be activated in response to electrical signals. The non-display area NDA may be covered by the bezel area BZA.

In an embodiment, pixels PX may be arranged in the display area DA. The pixels PX may be arranged in the first and second directions DR1 and DR2.

In an embodiment, the housing HAU may accommodate the display panel DP. The housing HAU may cover the display panel DP, and an upper surface of the display panel DP, i.e., the display surface IS, may be exposed. The housing HAU may cover a side surface and a bottom surface of the display panel DP, and the upper surface may be entirely exposed, however, the invention should not be limited thereto or thereby. According to another embodiment, the housing HAU may cover a portion of the upper surface in addition to the side surface and the bottom surface of the display panel DP.

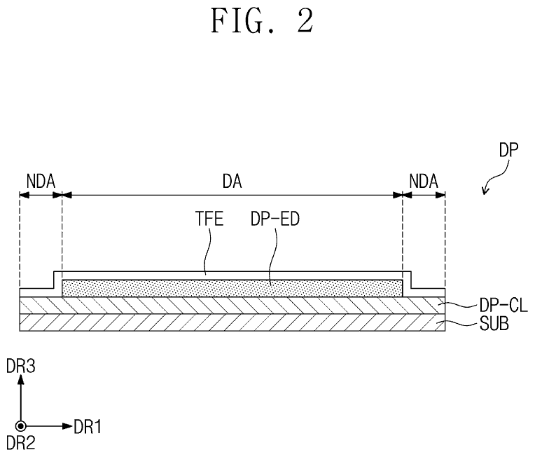

FIG. 2 is a cross-sectional view of the display device DP, according to an embodiment.

In an embodiment and referring to FIG. 2, the display panel DP may include a base layer SUB, a circuit element layer DP-CL disposed on the base layer SUB, a display element layer DP-ED disposed on the circuit element layer DP-CL, and an encapsulation layer TFE disposed on the display element layer DP-ED.

The base layer SUB may be disposed at a lowermost position of the display panel DP and may provide a base surface on which components of the display panel DP are disposed. The base layer SUB may include the display area DA and the non-display area NDA disposed adjacent to the display area DA.

The circuit element layer DP-CL may include a plurality of insulating layers and a circuit element. The insulating layers may include at least one inorganic layer and at least one organic layer. The circuit element may include signal lines, driving circuits, or the like, where the driving circuit may include a pixel driving circuit and a sensing driving circuit.

The insulating layer and the circuit element may be formed by forming an insulating layer, a semiconductor layer, and a conductive layer using a coating or depositing process and by selectively patterning the insulating layer, the semiconductor layer, and the conductive layer using a photolithography process and an etching process. Through the above processes, a semiconductor pattern, a conductive pattern, and the signal line, which are included in the circuit element layer DP-CL, may be formed.

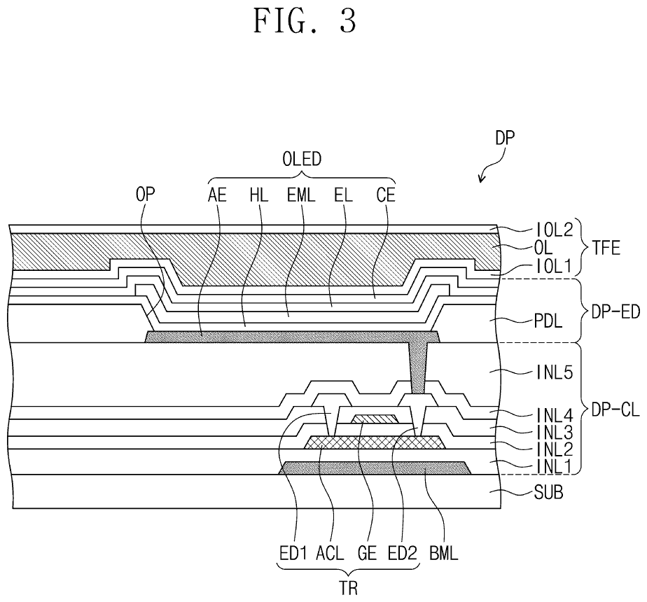

The display element layer DP-ED may be disposed on the circuit element layer DP-CL and may include a pixel definition layer PDL (refer to FIG. 3) and a display element OLED (refer to FIG. 3).

The encapsulation layer TFE may be disposed on the display element layer DP-ED and may cover the display element layer DP-ED. The encapsulation layer TFE may prevent moisture and oxygen from entering the display element layer DP-ED. The encapsulation layer TFE may have a stack structure of inorganic/organic/inorganic layers.

FIG. 3 is a cross-sectional view of the display panel DP, according to an embodiment.

FIG. 3 shows a cross-section of a portion of the pixel PX (refer to FIG. 1B) according to an embodiment.

In an embodiment, the display panel DP may include the base layer SUB, the circuit element layer DP-CL disposed on the base layer SUB, the display element layer DP-ED disposed on the circuit element layer DP-CL, and the encapsulation layer TFE disposed on the display element layer DP-ED.

In an embodiment, the base layer SUB may include a synthetic resin layer. The synthetic resin layer may include a thermosetting resin. In particular, the synthetic resin layer may be a polyimide-based resin layer, however, it should not be limited thereto or thereby. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. The base layer SUB may be a glass substrate, a metal substrate, or an organic/inorganic composite material substrate.

In an embodiment, the circuit element layer DP-CL may include a light shielding pattern BML, first, second, third, fourth, and fifth insulating layers INL1, INL2, INL3, INL4, and INL5, respectively, and a transistor TR. FIG. 3 shows one transistor TR connected to the light emitting element OLED, however, the structure of the transistor TR included in the circuit element layer DP-CL should not be limited thereto or thereby.

In an embodiment, the light shielding pattern BML may be disposed on the base layer SUB and may prevent an electric potential caused by a polarization phenomenon from affecting the transistor TR. The light shielding pattern BML may prevent an external light from reaching the transistor TR. According to an embodiment, the light shielding pattern BML may be a floating electrode isolated from other electrodes or lines.

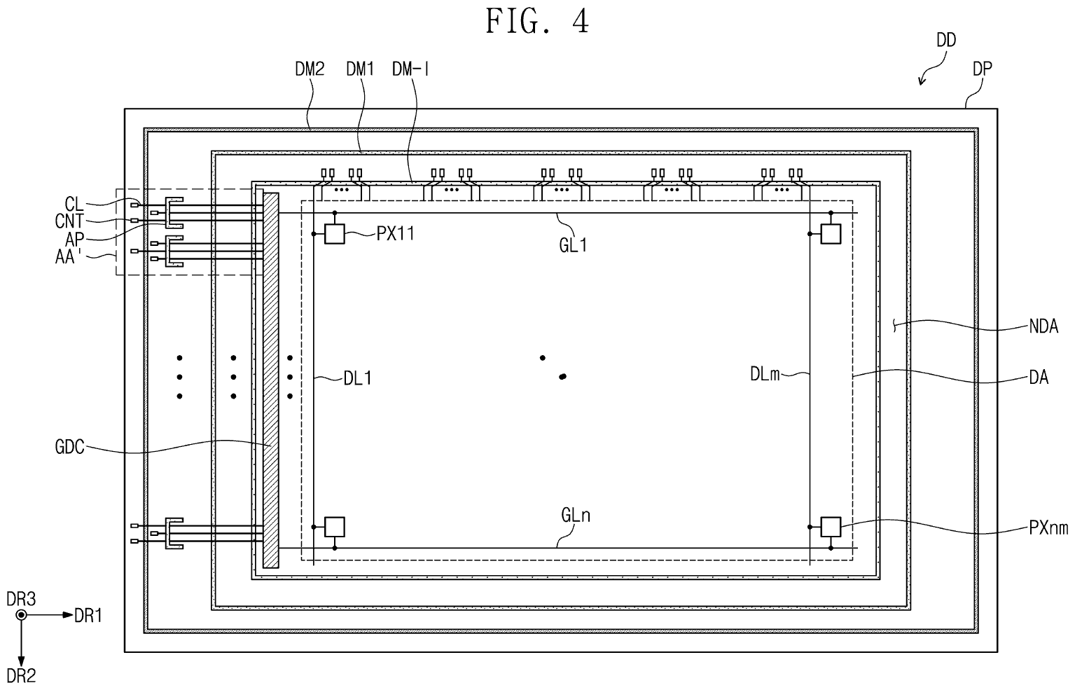

The light shielding pattern BML may be formed through the same process as and may include the same material as a data line DL (refer to FIG. 4). As an example, in an embodiment, the light shielding pattern BML may include copper or titanium.

In an embodiment, the first insulating layer INL1 may be disposed on the base layer SUB and may cover the light shielding pattern BML. The first insulating layer INL1 may be a functional layer. As an example, the first insulating layer INL1 may include a barrier layer and a buffer layer disposed on the barrier layer. The barrier layer may include a silicon oxide layer and a silicon nitride layer. Each of the silicon oxide layer and the silicon nitride layer may be provided in plural, and the silicon oxide layers may be alternately stacked with the silicon nitride layers. The buffer layer may include a silicon oxide layer and a silicon nitride layer, and the silicon oxide layer and the silicon nitride layer may be alternately stacked with each other.

The first insulating layer INL1 may prevent impurities present in the base layer SUB from entering the pixel PX (refer to FIG. 1B) during a manufacturing process. In particular, the first insulating layer INL1 may prevent impurities from being diffused to an active portion ACL of the transistor TR.

In an embodiment, the active portion ACL forming the transistor TR may be disposed on the first insulating layer INL1.

The active portion ACL may include polysilicon or amorphous silicon, however, it should not be limited thereto or thereby. According to an embodiment, the active portion ACL may include a metal oxide semiconductor.

The active portion ACL may include a channel area acting as a path through which electrons or holes move, a first ion-doped area, and a second ion-doped area that is spaced apart from the first ion-doped area with the channel area interposed therebetween.

In an embodiment, the second insulating layer INL2 may be disposed on the first insulating layer INL1 and may cover the active portion ACL. The second insulating layer INL2 may include an organic layer and/or an inorganic layer. The second insulating layer INL2 may include a plurality of inorganic thin layers. The inorganic thin layers may include a silicon nitride layer and a silicon oxide layer.

In an embodiment, a control electrode GE forming the transistor TR may be disposed on the second insulating layer INL2.

In an embodiment, the third insulating layer INL3 may be disposed on the second insulating layer INL2 and may cover the control electrode GE, where the third insulating layer INL3 may include an organic layer and/or an inorganic layer. The third insulating layer INL3 may include a plurality of inorganic thin layers or a plurality of organic thin layers. The inorganic thin layers may include a silicon nitride layer and a silicon oxide layer.

In an embodiment, a first electrode ED1 and a second electrode ED2 of the transistor TR may be disposed on the third insulating layer INL3. The first electrode ED1 and the second electrode ED2 may be connected to the active portion ACL through contact holes defined through the insulating layers INL2 and INL3, respectively.

In the present disclosure, each of the second and third insulating layers INL2 and INL3, respectively, may be referred to as an intermediate insulating layer.

In an embodiment, the fourth insulating layer INL4 may be disposed on the third insulating layer INL3 and may cover the first electrode ED1 and the second electrode ED2. The fourth insulating layer INLA may prevent a foreign substance from being diffused to the transistor. The fourth insulating layer INLA may protect the transistor TR. The fourth insulating layer INLA may include an organic layer and/or an inorganic layer. As an example, the fourth insulating layer INL4 may include silicon nitride (SiNx), silicon oxide (SiOx), and silicon oxynitride (SiOxNy).

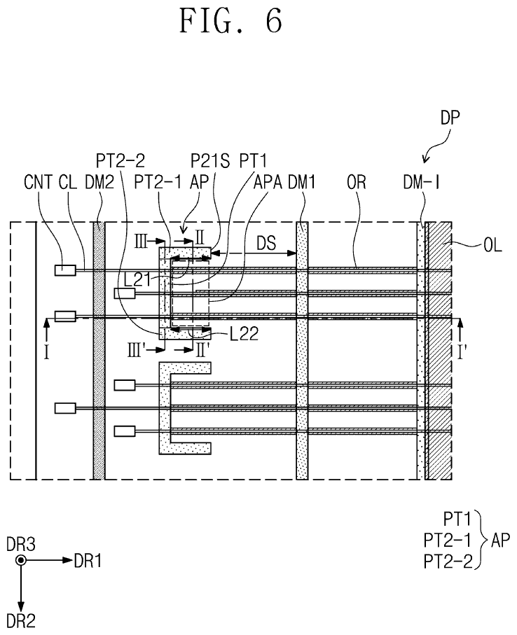

The fourth insulating layer INLA may provide a surface on which a shielding portion AP (refer to FIG. 6) described later is disposed.

In the present disclosure, the fourth insulating layer INLA may be referred to as an upper insulating layer.

In an embodiment, the fifth insulating layer INL5 may be disposed on the fourth insulating layer INL4 and may include an organic insulating material, for example, an organic polymer. The fifth insulating layer INL5 may be a planarization layer that provides a flat surface. The fifth insulating layer INL5 may include the same material as the shielding portion AP (refer to FIG. 6) described later.

In the present disclosure, the fifth insulating layer INL5 may be referred to as an organic insulating layer.

In an embodiment, the display element layer DP-ED may be disposed on the fifth insulating layer INL5 and may include the light emitting element OLED and the pixel definition layer PDL.

In an embodiment, the light emitting element OLED may include an anode electrode AE, a hole control layer HL, a light emitting layer EML, an electron control layer EL, and a cathode electrode CE.

The anode electrode AE may be disposed on the fifth insulating layer INL5 and may be connected to the second electrode ED2 through a contact hole defined through the fifth insulating layer INL5.

In an embodiment, the pixel definition layer PDL may be disposed on the fifth insulating layer INL5. A pixel opening OP may be defined through the pixel definition layer PDL. At least a portion of the anode electrode AE may be exposed through the pixel opening OP. An area of the anode electrode AE, which is exposed through the pixel opening OP, may correspond to a light emitting area. The pixel definition layer PDL may include the same material as the shielding portion AP (refer to FIG. 6) described later.

In an embodiment, the cathode electrode CE may be disposed on the anode electrode AE. The cathode electrode CE may be a common electrode, however, the invention should not be limited thereto or thereby. The light emitting layer EML that emits a light may be disposed between the anode electrode AE and the cathode electrode CE.

In an embodiment, the hole control layer HL may be disposed between the anode electrode AE and the light emitting layer EML and may provide holes provided thereto from the anode electrode AE to the light emitting layer EML. The hole control layer HL may be provided in a plurality of layers. As an example, in an embodiment, the hole control layer HL may include a hole injection layer and a hole transport layer.

In an embodiment, the electron control layer EL may be disposed between the cathode electrode CE and the light emitting layer EML and may provide electrons provided thereto from the cathode electrode CE to the light emitting layer EML. The electron control layer EL may be provided in a plurality of layers. As an example, in an embodiment, the electron control layer EL may include an electron injection layer and an electron transport layer.

In an embodiment, the encapsulation layer TFE may be disposed on the display element layer DP-ED. The encapsulation layer TFE may encapsulate the display element layer DP-ED and may protect the display element layer DP-ED from external oxygen or moisture.

The encapsulation layer TFE may include a first inorganic layer IOL1, an organic layer OL disposed on the first inorganic layer IOL1, and a second inorganic layer IOL2 disposed on the organic layer OL. FIG. 3 shows a structure in which the encapsulation layer TFE includes two inorganic layers and one organic layer as a representative example. However, the invention should not be limited thereto or thereby. As an example, in an embodiment, the encapsulation layer TFE may include three inorganic layers and two organic layers, and in this case, the inorganic layers may be alternately stacked with the organic layers.

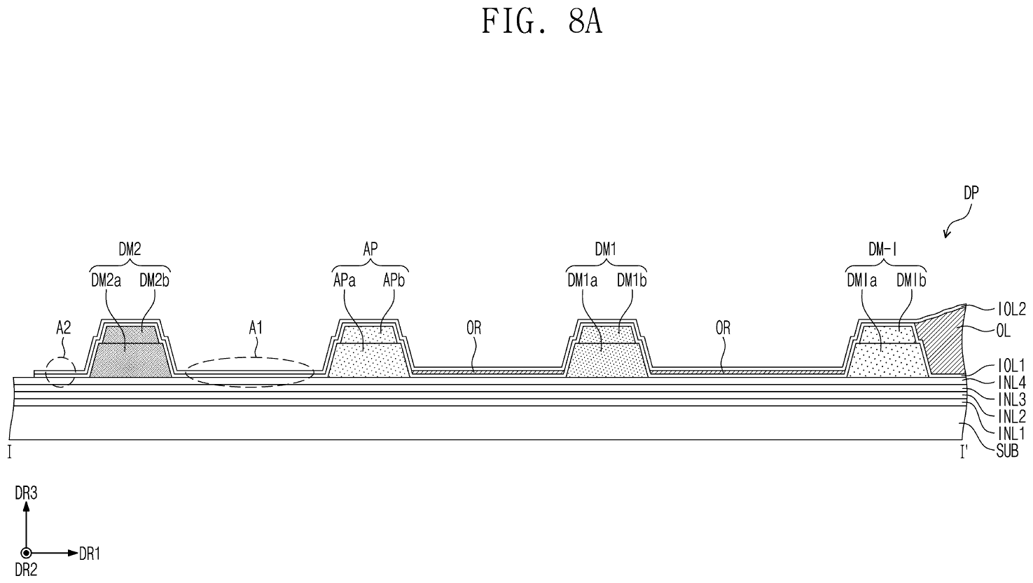

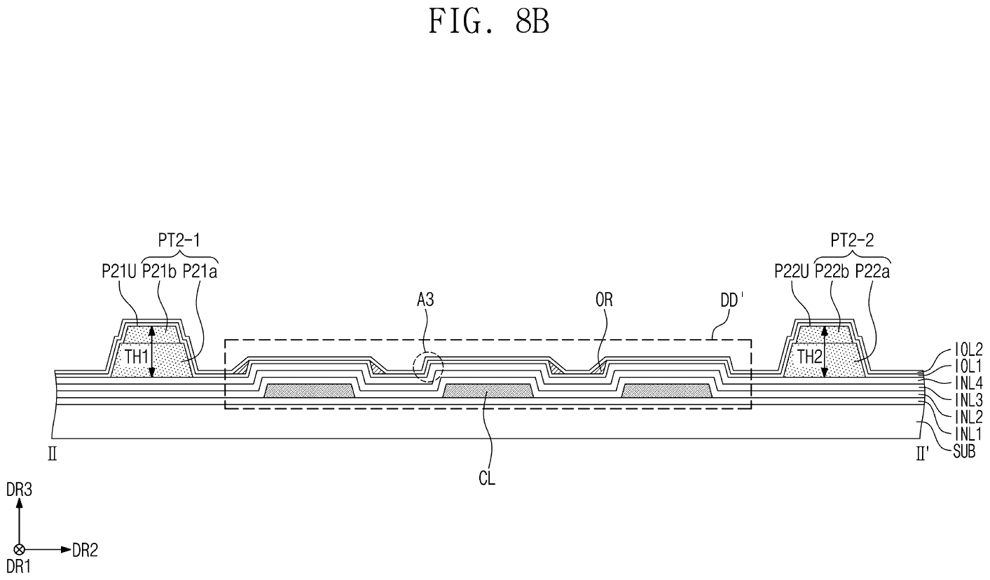

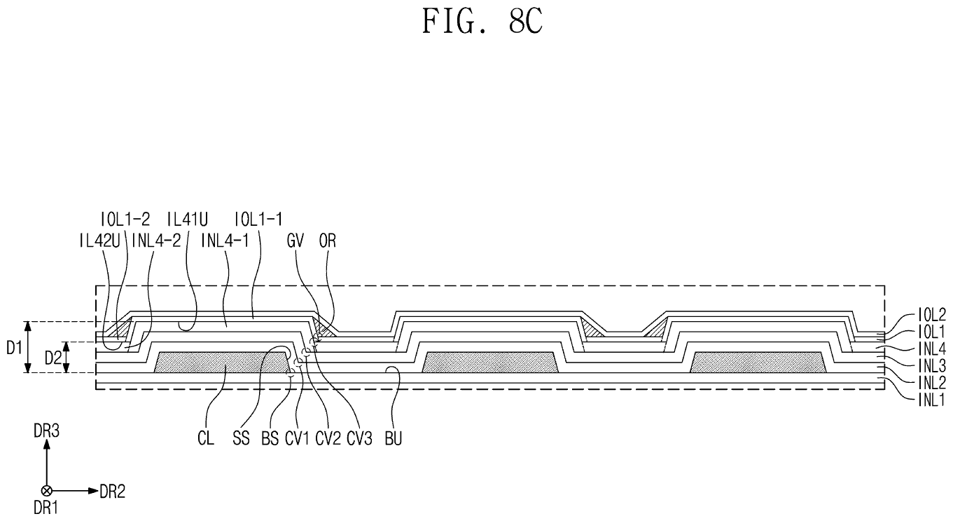

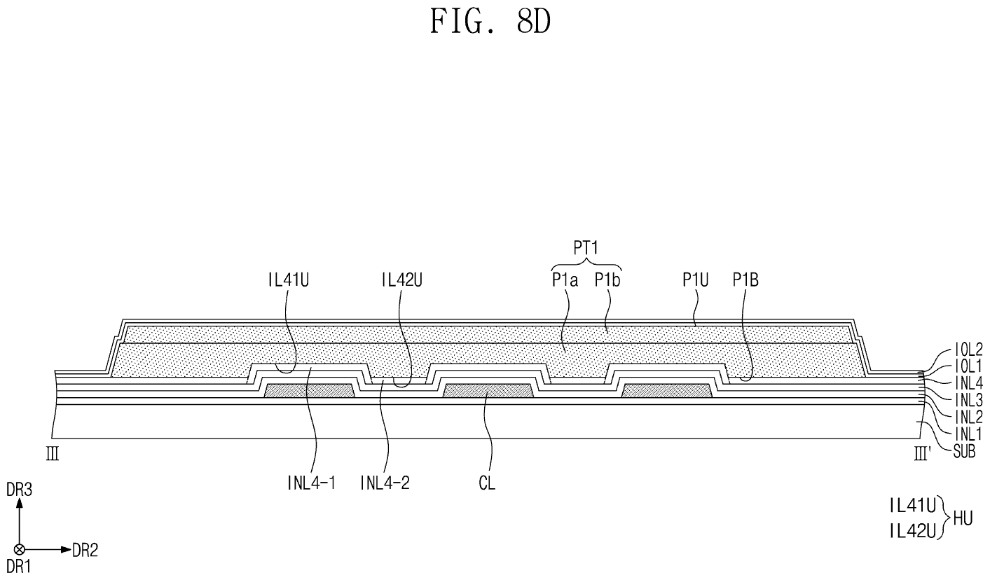

In an embodiment, the first inorganic layer IOL1 may cover the light emitting element OLED. However, the first inorganic layer IOL1 may extend to the non-display area NDA (refer to FIG. 2) to cover components, such as the shielding portion AP (refer to FIG. 6), disposed in the non-display area NDA, and this will be described later with reference to FIG. 8A.

The first inorganic layer IOL1 may be hydrophobic plasma-treated or hydrophilic plasma-treated to control a flow of an organic material coated on the first inorganic layer IOL1.

In an embodiment, the organic layer OL may include an organic material including a monomer or a polymer. As an example, the organic layer OL may include at least one of an acrylic resin, an epoxy resin, and silicon oxycarbide (SiOC), however, the organic layer OL should not be limited thereto or thereby.

The organic layer OL may be formed by a solution process, such as a spin coating, slit coating, or inkjet process. However, since an organic material solution used in the solution process has fluidity, the organic material used in the process of forming the organic layer OL may be overcoated to areas other than the display area DA (refer to FIG. 2). Accordingly, an ashing process may be further performed to remove the overcoated organic material.

In an embodiment, the second inorganic layer IOL2 may be disposed on the organic layer OL. However, the second inorganic layer IOL2 may extend to the non-display area NDA (refer to FIG. 2) to cover components, such as the shielding portion AP (refer to FIG. 6), disposed in the non-display area NDA, and this will be described later with reference to FIG. 8A.

FIG. 4 is a plan view of the display panel DP, according to an embodiment.

In an embodiment and referring to FIG. 4, the display panel DP may include pixels PX11 to PXnm, signal lines GL1 to GLn and DL1 to DLm, driving lines CL, an initial dam DM-I, a first dam DM1, the shielding portion AP, and a second dam DM2. The signal lines GL1 to GLn and DL1 to DLm, the initial dam DM-I, and the shielding portion AP may be components included in the circuit element layer DP-CL described with reference to FIG. 3.

In an embodiment, the pixels PX11 to PXnm may be arranged in a matrix form. FIG. 4 shows that the pixels PX11 to PXnm are arranged in the first direction DR1 and the second direction DR2 as a representative example. However, the arrangement of the pixels PX11 to PXnm should not be limited thereto or thereby. As an example, the pixels PX11 to PXnm may be arranged in the form of a pentile (PENTILE®).

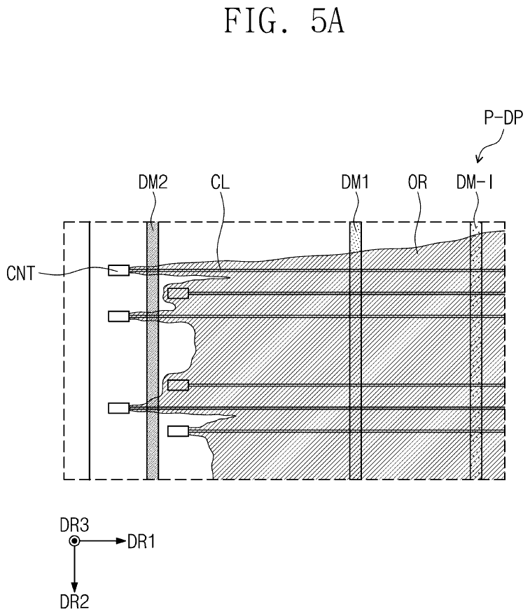

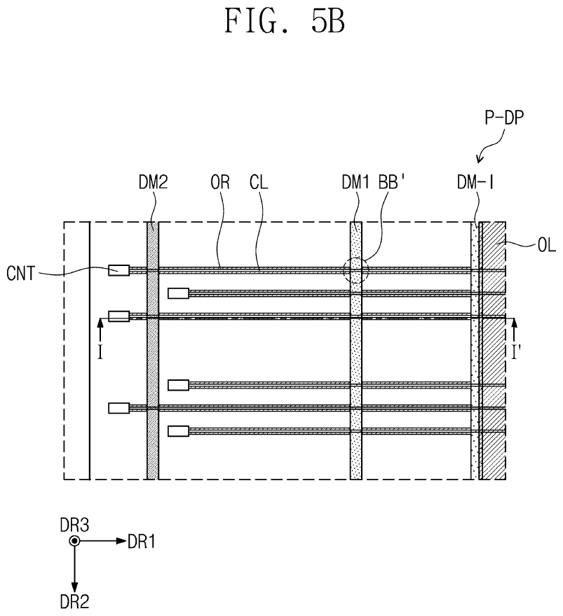

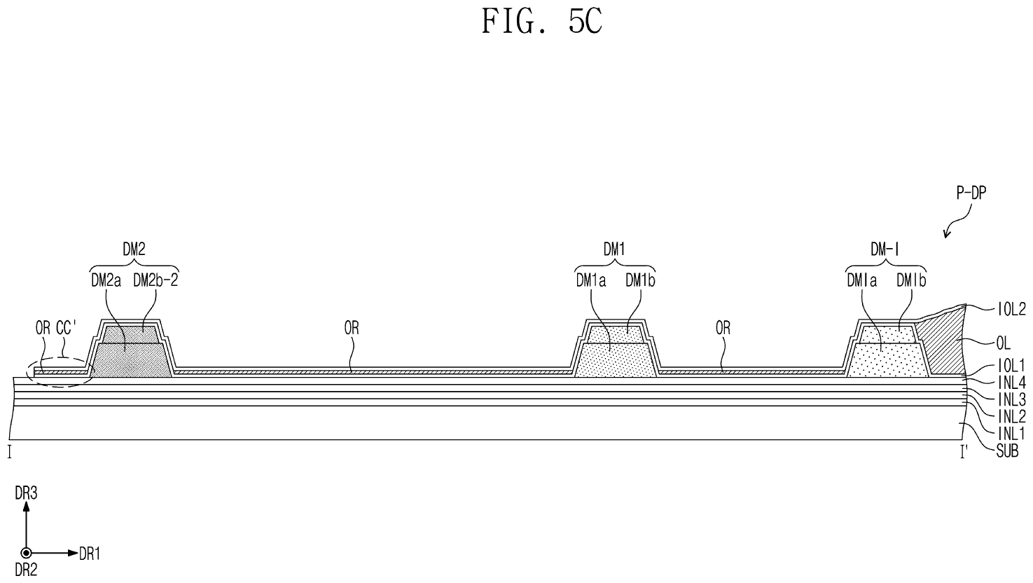

Each of the pixels PX11 to PXnm may be connected to a corresponding gate line among the gate lines GL1 to GLn and a corresponding data line among the data lines DL1 to DLm. Each of the pixels PX11 to PXnm may include a pixel driving circuit CC (refer to FIG. 5) and the light emitting element OLED (refer to FIG. 3).

The signal lines GL1 to GLn and DL1 to DLm may include the gate lines GL1 to GLn and the data lines DL1 to DLm.

The gate lines GL1 to GLn may be arranged to overlap the display area DA. However, a portion of each of the gate lines GL1 to GLn may extend to the non-display area NDA.

In an embodiment, the gate lines GL1 to GLn may extend in the first direction DR1 and may be arranged in the second direction DR2. The gate lines GL1 to GLn may be electrically connected to a gate driving circuit GDC and the pixels PX11 to PXnm. The portion of each of the gate lines GL1 to GLn, which extends to the non-display area NDA, may be connected to the gate driving circuit GDC. Among the pixels PX11 to PXnm, pixels connected to each of the gate lines GL1 to GLn may be arranged in the first direction DR1.

In an embodiment, the data lines DL1 to DLm may be arranged to overlap the display area DA. The data lines DL1 to DLm may extend in the second direction DR2 and may be arranged in the first direction DR1. The data lines DL1 to DLm may be electrically connected to the pixels PX11 to PXnm. Among the pixels PX11 to PXnm, pixels connected to each of the data lines DL1 to DLm may be arranged in the second direction DR2.

The data lines DL1 to DLm may be insulated from the gate lines GL1 to GLn while intersecting the gate lines GL1 to GLn.

In an embodiment, the gate driving circuit GDC may be disposed in the non-display area NDA. FIG. 4 shows one gate driving circuit GDC disposed in the non-display area NDA and disposed adjacent to one side of the display area DA. However, the invention should not be limited thereto or thereby, and the gate driving circuit GDC may be disposed at both sides of the display area DA in the first direction DR1.

The gate driving circuit GDC may output signals to the display panel DP. The signals output from the gate driving circuit GDC may be applied to the pixels PX through the gate lines GL1 to GLn.

In an embodiment, the gate driving circuit GDC may be integrated by an OSG (oxide silicon gate driver circuit) process, however, the invention should not be limited thereto or thereby. According to another embodiment, the gate driving circuit GDC may be integrated in the display panel DP by an ASG (amorphous silicon gate driver circuit) process.

In an embodiment, the initial dam DM-I may be disposed in the non-display area NDA. The initial dam DM-I may be disposed on the upper insulating layer INL4 (refer to FIG. 3). When viewed in a plane, the initial dam DM-I may surround the display area DA.

In an embodiment, the first dam DM1 may be disposed in the non-display area NDA. The first dam DM1 may be disposed on the upper insulating layer INLA (refer to FIG. 3). When viewed in a plane, the first dam DM1 may surround the display area DA and the initial dam DM-I. The first dam DM1 may be spaced farther apart from the display area DA than the initial dam DM-I is.

In an embodiment, the second dam DM2 may be disposed in the non-display area NDA. The second dam DM2 may be disposed on the upper insulating layer INL4 (refer to FIG. 3). When viewed in a plane, the second dam DM2 may surround the first dam DM1. When viewed in a plane, the second dam DM2 may surround the display area DA and the first dam DM1. The second dam DM2 may be spaced farther apart from the display area DA than the first dam DM1 is.

In an embodiment, the initial dam DM-I, the first dam DM1, and the second dam DM2 may control the flow of the organic material for the organic layer OL when the organic layer OL included in the encapsulation layer TFE (refer to FIG. 3) is formed. That is, even though the organic material with fluidity flows from the display area DA to the non-display area NDA, the organic material may be blocked by the initial dam DM-I. Accordingly, the initial dam DM-I may define a boundary of the organic layer OL (refer to FIG. 3) when viewed in a plane. However, the organic material flowing over the initial dam DM-I may be additionally blocked by the first and second dams DM1 and DM2, respectively.

Each of the initial dam DM-I, the first dam DM1, and the second dam DM2 may include at least one layer containing an organic material. The initial dam DM-I, the first dam DM1, and the second dam DM2 may be formed through the same process as and may include the same material as the fifth insulating layer INL5 (refer to FIG. 3) and the pixel definition layer PDL (refer to FIG. 3).

In an embodiment, the driving lines CL may be disposed on the first insulating layer INL1 (refer to FIG. 3), however, the invention should not be limited thereto or thereby. According to another embodiment, the driving line CL may be disposed on the second to fourth insulating layers INL2 to INLA.

The driving lines CL may be spaced apart from each other in the second direction DR2.

The driving lines CL may extend in the first direction DR1. The driving lines CL may extend with different lengths in the first direction. The driving lines CL may overlap the initial dam DM-I, the first dam DM1, the shielding portion AP, or the second dam DM2.

One end of each of the driving lines CL may be connected to the gate driving circuit GDC, and the other end of each of the driving lines CL may be connected to a signal generating member (not shown). The other end of the driving lines CL may be connected to the signal generating member via contact holes CNT defined through at least a portion of the insulating layers INL1 to INL4 (refer to FIG. 3).

In an embodiment, each of the contact holes CNT may be defined inside or outside the second dam DM2 depending on the extension length of each driving line CL. In the present disclosure, the inside of the second dam DM2 may refer to a direction directed toward the display area DA and based on the second dam DM2, and the outside of the second dam DM2 may refer to a direction directed toward an outer portion of the display panel DP and based on the second dam DM2. FIG. 4 shows a structure in which some of the contact holes CNT are defined outside the second dam DM2 and the other of the contact holes CNT are defined inside the second dam DM2 as a representative example, however, the invention should not be limited thereto or thereby. According to an embodiment, some of the contact holes CNT may be defined to overlap the second dam DM2.

In an embodiment, the driving lines CL may transmit an electrical signal generated by the signal generating member to drive the gate driving circuit GDC. Although not shown separately, the signal generating member may include a transistor. The electrical signal generated by the signal generating member may be a clock signal.

In an embodiment, the shielding portion AP may be disposed on the upper insulating layer INL4 (refer to FIG. 3) and may be provided in plural. The shielding portions AP may be disposed between the first dam DM1 and the second dam DM2. The shielding portions AP may be spaced farther apart from the display area DA than the gate driving circuit GDC is. That is, the shielding portions AP may be disposed closer to the outer portion of the display panel DP than the gate driving circuit GDC is.

The shielding portion AP may prevent the organic material for the organic layer OL from flowing toward the second dam DM2 after overflowing the first dam DM1 in the process of forming the organic layer OL (refer to FIG. 3). That is, the shielding portion AP may block the organic material not to allow the organic material to travel from the display area DA to the non-display area NDA after flowing over the first dam DM1.

FIG. 5A is a plan view of a display panel P-DP, according to a comparative example. FIG. 5B is a plan view of the display panel P-DP, according to a comparative example. FIG. 5C is a cross-sectional view of the display panel P-DP taken along a line I-I′ of FIG. 5B.

Hereinafter, defects of the display panel P-DP, according to the comparative example, that does not include the shielding portion AP (refer to FIG. 6) will be described with reference to FIGS. 5A to 5C.

FIG. 5A shows the display panel P-DP, according to the comparative example, corresponding to an area AA′ shown in FIG. 4.

A liquid organic material may overflow into a direction toward an outer portion of the display panel DP-D in a process of forming an organic layer (refer to OL of FIG. 3) included in an encapsulation layer (refer to TFE of FIG. 3) using a solution process. That is, the organic material may overflow an initial dam DM-I.

In the present disclosure, the organic material that overflows the initial dam DM-I and that is coated may be referred to as an over-organic material OR. In an embodiment, the over-organic material OR may include a hardened organic material as well as a liquid organic material with fluidity. A portion of the over-organic material OR may overflow not only the initial dam DM-I but also a first dam DM1 or a second dam DM2.

The overflow phenomenon of the over-organic material OR may occur on an area where a first inorganic layer (refer to IOL1 of FIG. 3) is disposed adjacent to a side surface of a driving line CL. FIG. 5A shows the over-organic material OR that overflows into the outer portion of the display panel P-DP along a direction directed parallel to the first direction DR1 in the display panel, according to the comparative example as a representative example.

The phenomenon in which the over-organic material OR moves along the area disposed adjacent to the side surface of the driving line CL may be explained by a capillary phenomenon caused by an inorganic curved portion (refer to GV of FIG. 8C) defined in the first inorganic layer (refer to IOL1 of FIG. 8C). This will be described in detail with reference to FIGS. 8B and 8C.

FIG. 5B shows a portion of the display panel P-DP on which an ashing process is performed to remove the over-organic material OR after the process of coating the organic material to form the organic layer (refer to OL of FIG. 3), according to the comparative example.

Referring to FIG. 5B, at least a portion of over-organic material OR may be removed by the ashing process.

The ashing process to remove the over-organic material OR may be effectively performed in an area where the first inorganic layer IOL1 (refer to FIG. 3) has a flat surface. However, the ashing process may not be effectively performed in an area where the first inorganic layer IOL1 is not flat due to uneven portions of the first inorganic layer IOL1.

As an example, since the initial dam DM-I, the first dam DM1, and the second dam DM2 have the flat upper surface, the first inorganic layer IOL1 (refer to FIG. 3) may have also a flat surface in an area overlapping the upper surfaces. An area BB′ of FIG. 5B shows a state in which the over-organic material OR coated on the first inorganic layer IOL1 is removed by the ashing process in an area overlapping the upper surface of the first dam DM1.

However, since the inorganic curved portion (refer to GV of FIG. 8C) is defined in the area where the first inorganic layer IOL1 (refer to FIG. 3) is disposed adjacent to the side surface of the driving lines CL, the ashing process to remove the over-organic material OR may not be smoothly performed. FIG. 5B shows a state in which the over-organic material OR remains in the area adjacent to the driving lines CL. The reason for the formation of the inorganic curved portion GV and the structure of the inorganic curved portion GV will be described in detail with reference to FIGS. 8B and 8C.

FIG. 5C is a cross-sectional view of the display panel P-DP taken along the line I-I′ of FIG. 5B.

A portion of the over-organic material OR, which is filled in the inorganic curved portion GV (refer to FIG. 8C), may remain on the outer portion of the display panel P-DP based on the second dam DM2.

An area CC′ shown in FIG. 5C shows the over-organic material OR remaining after overflowing the second dam DM2. The over-organic material OR remaining in the area CC′ may act as a moisture/oxygen permeation path. Accordingly, reliability of the display panel P-DP, according to the comparative example, may be deteriorated due to the moisture/oxygen that permeates through the over-organic material OR remaining in the area CC′.

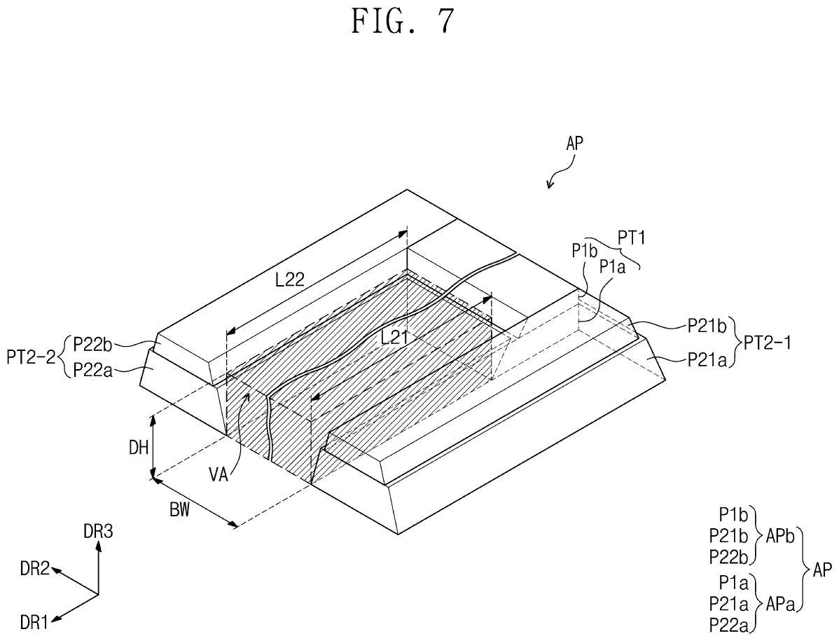

FIG. 6 is a plan view of a portion of the display panel DP corresponding to an area AA′ of FIG. 4, according to an embodiment. FIG. 7 is a perspective view of the shielding portion AP, according to an embodiment.

Hereinafter, the structure and location of the shielding portion AP will be described in detail with reference to FIGS. 6 and 7.

In an embodiment, the shielding portion AP may be disposed between the first dam DM1 and the second dam DM2.

The shielding portion AP may be provided in plural, and the shielding portions AP may be spaced apart from each other in the second direction DR2.

The shielding portions AP may include a first portion PT1 and second portions PT2-1 and PT2-2. However, the first portion PT1 and the second portions PT2-1 and PT2-2 are defined for the convenience of explanation of the structure of the shielding portions AP, and the shielding portions AP may have a continuous integral form.

The first portion PT1 may overlap at least one of the driving lines CL and may extend in the second direction DR2.

The second portions PT2-1 and PT2-2 may include a second-first portion PT2-1 that protrudes from one end of the first portion PT1 in the first direction DR1 and that does not overlap the driving lines CL and a second-second portion PT2-2 that protrudes from the other end of the first portion PT1 in the first direction DR1 and that does not overlap the driving lines CL.

FIG. 6 shows a structure in which the first portion PT1 included in the shielding portions AP overlaps three driving lines CL as a representative example. However, the number of the driving lines CL overlapping each shielding portion AP should not be particularly limited.

In an embodiment as shown in FIG. 6, each of the first and second portions PT1, PT2-1, and PT2-2 has a quadrangular shape when viewed in a plane. However, the invention should not be limited thereto or thereby. As an example, each of the portions PT1, PT2-1, and PT2-2 may have a chamfered shape in which a portion at the corners is cut out.

In an embodiment, the shielding portion AP may be spaced apart from the first dam DM1. A distance between the shielding portion AP and the first dam DM1 may be referred to as a separation distance DS. The separation distance DS may be defined as a distance from a surface of a portion of the second-first portion PT2-1 or the second-second portion PT2-2 that faces the first dam DM1 and that is closer to the first dam DM1 to a side surface of the first dam DM1. FIG. 6 shows the separation distance DS from a surface P21S of the second-first portion PT2-1, which faces the first dam DM1, to the first dam DM1.

In an embodiment, the protruding lengths of the second-first portion PT2-1 and the second-second portion PT2-2 from the first portion PT1 in the first direction DR1 may be referred to as a first protrusion length L21 and a second protrusion length L22, respectively.

In an embodiment, the first protrusion length L21 may be the same as the second protrusion length L22. In this case, each of the protrusion lengths L21 and L22 may be equal to or greater than a value obtained by multiplying the number of the driving lines CL overlapping the first portion PT1 by about 1.8 micrometers and equal to or smaller than a value obtained by multiplying the number of the driving lines CL overlapping the first portion PT1 by about 2.2 micrometers. As an example, when the first portion PT1 included in the shielding portion AP overlaps three driving lines CL, each of the first protrusion length L21 and the second protrusion length L22 may be equal to or greater than about 5.4 micrometers and equal to or smaller than about 6.6 micrometers. However, the invention should not be limited thereto or thereby, and the first protrusion length L21 and the second protrusion length L22 may be different from each other.

In an embodiment, the shielding portion AP may block the flow of the over-organic material OR, which is caused by the capillary phenomenon. That is, the flow of the over-organic material OR that moves to the direction toward the outer portion of the display panel DP over the first dam DM1 may be blocked by the shielding portion AP.

In an embodiment, since the first portion PT1 overlaps the driving lines CL, the over-organic material OR flowing adjacent to the driving lines CL may be in contact with a surface of the first portion PT1, which faces the first dam DM1. Accordingly, the first portion PT1 may block the over-organic material OR flowing in a direction along the first direction DR1 by the capillary phenomenon.

In an embodiment, at least a portion of the over-organic material OR, which is in contact with the first portion PT1, may flow in a direction directed parallel to the second direction DR2. The flowing of the over-organic material OR in the direction directed parallel to the second direction DR2 may be blocked by the second-first portion PT2-1 and the second-second portion PT2-2.

That is, the shielding portion AP may block the flowing of the over-organic material OR that flows in both the direction along the first direction DR1 and the direction that is parallel to the second direction DR2 by the capillary phenomenon.

In an embodiment and referring to FIG. 6, an area defined inside the shielding portion AP may be defined as a shielding portion area APA. The shielding portion area APA may be defined between the second-first portion PT2-1 and the second-second portion PT2-2. The over-organic material OR blocked by the shielding portion AP may be accumulated in the shielding portion area APA.

In an embodiment and referring to FIG. 7, the shielding portion AP may have a multi-layer structure. According to an embodiment, the first portion PT1 may include a first layer P1a and a second layer P1b disposed on the first layer P1a, the second-first portion PT2-1 may include a first layer P21a and a second layer P21b disposed on the first layer P21a, and the second-second portion PT2-2 may include a first layer P22a, and a second layer P22b disposed on the first layer P22a.

In an embodiment, the shielding portion AP may include a first shielding layer APa and a second shielding layer APb disposed on the first shielding layer APa. The first shielding layer APa may include the first layers P1a, P21a, and P22a, and the second shielding layer APb may include the second layers P1b, P21b, and P22b.

In an embodiment, the first shielding layer APa may be formed through the same process as and may include the same material as the fifth insulating layer INL5 (refer to FIG. 3). The second shielding layer APb may be formed through the same process as and may include the same material as the pixel definition layer PDL (refer to FIG. 3).

However, the invention should not be limited thereto or thereby, and the shielding portion AP may have a single-layer structure or a multi-layer structure of three or more layers.

In an embodiment, a barrier space VA may be defined in the shielding portion AP. Referring to FIG. 7, the barrier space VA may be defined as a space in the form of a rectangular parallelepiped, with its bottom defined by an area on the upper insulating layer INL4 (refer to FIG. 3) disposed between the second-first portion and the second-second portion and its height defined by a height DH of the shielding portion AP.

In an embodiment, a volume of the barrier space VA may be determined by a value obtained by multiplying a barrier width BW between the second-first portion PT2-1 and the second-second portion PT2-2, one protrusion length smaller than the other protrusion length between the first protrusion length L21 of the second-first portion PT2-1 protruding from the first portion PT1 directed in the first direction DR1 and the second protrusion length L22 of the second-second portion PT2-2 protruding from the first portion PT1 directed in the first direction DR1, and the height DH of the shielding portion AP.

When the volume of the barrier space VA increases, an effect of the shielding portion AP in blocking the over-organic material OR may increase. However, when the volume of the barrier space VA is too large, there may not be enough space available for the placement of the shielding portion AP in the display panel DP (refer to FIG. 2). Accordingly, it is preferred that the volume of the barrier space VA is equal to or greater than about twelve times and equal to or smaller than about thirty times a volume of the over-organic material OR (refer to FIG. 6) that is disposed between the second portions PT2-1 and PT2-2. However, the invention should not be limited thereto or thereby.

FIG. 8A is a cross-sectional view of the display panel taken along a line I-I′ of FIG. 6, according to an embodiment. FIG. 8B is a cross-sectional view of the display panel taken along a line II-II′ of FIG. 6, according to an embodiment. FIG. 8C is a cross-sectional view of the display panel corresponding to an area DD′ of FIG. 8B, according to an embodiment.

In an embodiment, the initial dam DM-I, the first dam DM1, the shielding portion AP, and the second dam DM2 may be disposed on the fourth insulating layer INL4.

The initial dam DM-I, the first dam DM1, the shielding portion AP, and the second dam DM2 may be covered by the first inorganic layer IOL1 and the second inorganic layer IOL2.

In an embodiment, ends of the first inorganic layer IOL1 and the second inorganic layer IOL2 may be disposed inside an end of the display panel DP.

In an embodiment, the first dam DM1 may include a first layer DM1a disposed on the upper insulating layer INL4 and a second layer DM1b disposed on the first layer DM1a. Each of the first layer DM1a and the second layer DM1b may have a trapezoidal shape when viewed in the cross-section, however, the invention should not be limited thereto or thereby. As an example, the first dam DM1 may have a single-layer structure or the first layer DM1a or the second layer DM1b may have a shape rather than the trapezoidal shape when viewed in the cross-section.

In an embodiment, the second dam DM2 may include a first layer DM2a disposed on the upper insulating layer INLA and a second layer DM2b disposed on the first layer DM2a. Each of the first layer DM2a and the second layer DM2b may have a trapezoidal shape when viewed in the cross-section, however, the invention should not be limited thereto or thereby. As an example, the second dam DM2 may have a single-layer structure or the first layer DM2a or the second layer DM2b may have a shape rather than the trapezoidal shape when viewed in the cross-section.

In an embodiment, the shielding portion AP may include the first shielding layer APa disposed on the upper insulating layer INL4 and the second shielding layer APb disposed on the first shielding layer APa. The cross-section of the first shielding layer APa shown in FIG. 8A may be the cross-section of the first layer P1a (refer to FIG. 7), and the cross-section of the second shielding layer APb may be the cross-sectional of the second layer P1b (refer to FIG. 7).

In an embodiment, the first shielding layer APa and the first layers DM1a, DM1a, and DM2a may be formed through the same process as and may include the same material as the fifth insulating layer INL5 (refer to FIG. 3). Accordingly, the first shielding layer APa may include an organic material.

In an embodiment, the second shielding layer APb and the second layers DM1b, DM1b, and DM2b may be formed through the same process as and may include the same material as the pixel definition layer PDL (refer to FIG. 3). Accordingly, the second shielding layer APb may include an organic material.

According to an embodiment, the over-organic material OR may not remain in an area A1 disposed between the shielding portion AP and the second dam DM2. That is, the flowing of the over-organic material OR in the process of forming the organic layer OL may be blocked by the shielding portion AP, and thus, the over-organic material OR may not remain in the area A1 disposed between the shielding portion AP and the second dam DM2.

Accordingly, the first inorganic layer IOL1 may be in contact with the second inorganic layer IOL2 in the area A1.

In an embodiment, the over-organic material OR may not remain in an area A2 disposed between the second dam DM2 and the outer portion of the display panel DP since the over-organic material OR is blocked by the second dam DM2. That is, according to the display panel DP, the formation of the moisture/oxygen permeation path may be prevented by the second dam DM2. Accordingly, the display panel DP may have higher reliability than the display panel P-DP (refer to FIG. 5C) according to the comparative example.

In an embodiment and referring to FIGS. 8B and 8C, the driving lines CL may be disposed on the first insulating layer INL1. The driving lines CL may be covered by the insulating layers INL2 to INLA and the inorganic layers IOL1 and IOL2.

Due to a thickness of the driving lines CL, a stepped portion BS may be defined between an upper surface BU of the first insulating layer INL1 and a side surface SS of each of the driving lines CL.

A first curved portion CV1 and a second curved portion CV2, which are curved corresponding to a shape of the stepped portion BS, may be respectively defined in the second insulating layer INL2 and the third insulating layer INL3. The first and second curved portions CV1 and CV2 may be referred to as an intermediate curved portion in the following descriptions.

A third curved portion CV3 curved corresponding to the shape of the first and second curved portions CV1 and CV2 may be defined in the fourth insulating layer INLA. The third curved portion CV3 may be referred to as an upper curved portion.

The upper insulating layer INL4 may include a first upper portion INL4-1 and a second upper portion INLA-2. However, the first upper portion INL4-1 and the second upper portion INLA-2 are defined for the convenience of explanation of the structure, and the upper insulating layer INLA may have a continuous integral form.

The first upper portion INL4-1 may overlap one of the driving lines CL and may cover the second curved portion CV2. An upper surface IL41U of the first upper portion INL4-1 may be spaced apart from the upper surface BU of the first insulating layer INL1 by a first distance D1.

The second upper portion INL4-2 may not overlap the driving lines CL and may be disposed between the first upper portions INL4-1 disposed adjacent to each other. An upper surface IL42U of the second upper portion INL4-2 may be spaced apart from the upper surface BU of the first insulating layer INL1 by a second distance D2.

In an embodiment, since the first upper portion INL4-1 may overlap the driving lines CL and the second upper portion INL4-2 may not overlap the driving lines CL, the first distance D1 may be greater than the second distance D2.

In an embodiment, the second-first portion PT2-1 and the second-second portion PT2-2 may be disposed on the upper insulating layer INL4.

Each of the second-first portion PT2-1 and the second-second portion PT2-2 may not overlap the driving lines CL. In addition, each of the second-first portion PT2-1 and the second-second portion PT2-2 may overlap the second upper portion INL4-2.

In an embodiment, an upper surface P21U of the second-first portion and an upper surface P22U of the second-second portion may be flat. That is, a first thickness TH1 in the third direction DR3 of the second-first portion PT2-1 may be uniform in the second direction DR2 in an area overlapping the upper surface P21U of the second-first portion. In addition, a second thickness TH2 in the third direction DR3 of the second-second portion PT2-2 may be uniform in the second direction DR2 in an area overlapping the upper surface P22U of the second-second portion.

In an embodiment, the first inorganic layer IOL1 may cover the second-first portion PT2-1, the second-second portion PT2-2, and the upper insulating layer INL4.

In an embodiment, the first inorganic layer IOL1 may include a first inorganic portion IOL1-1 and a second inorganic portion IOL1-2. However, the first inorganic portion IOL1-1 and the second inorganic portion IOL1-2 are defined for the convenience of explanation, and the first inorganic layer IOL1 may have a continuous integral shape.

The first inorganic portion IOL1-1 may overlap one of the driving lines CL and may cover the upper curved portion CV3. The first inorganic portion IOL1-1 may overlap the first upper portion INL4-1.

The second inorganic portion IOL1-2 may not overlap the driving lines CL and may be disposed between the first inorganic portions IOL1-1 that are disposed adjacent to each other. The second inorganic portion IOL1-2 may overlap the second upper portion INL4-2.

In an embodiment, since the first inorganic layer IOL1 is disposed on the upper insulating layer INL4, the inorganic curved portion GV curved corresponding to a shape of the upper curved portion CV3 may be defined in the first inorganic layer IOL1.

In an embodiment, at least a portion of the over-organic material OR may be disposed on the inorganic curved portion GV, where the over-organic material OR disposed on the inorganic curved portion GV may be covered by the second inorganic layer IOL2.

In an embodiment and referring to FIG. 8C, the over-organic material OR disposed on the inorganic curved portion GV has a triangular shape when viewed in the cross-section, however, the invention should not be limited thereto or thereby. Since the over-organic material OR is formed due to the overflow phenomenon of the liquid organic material, the over-organic material OR may have an irregular shape.

In an embodiment, since the over-organic material OR is formed by the overflow of the organic material, the over-organic material OR may not be disposed on a portion of the inorganic curved portion GV. FIG. 8B shows the inorganic curved portion GV on which the over-organic material OR is not disposed in an area A3 as a representative example.

The second inorganic layer IOL2 may cover the first inorganic layer IOL1 and the over-organic material OR disposed on the inorganic curved portion GV.

FIG. 8D is a cross-sectional view of the display panel taken along a line III-III′ of FIG. 6, according to an embodiment.

In an embodiment and referring to FIG. 8D, the first inorganic layer IOL1 and the upper insulating layer INL4 may be partially spaced apart from each other with the first portion PT1 interposed therebetween. Accordingly, the first inorganic layer IOL1 may not be curved corresponding to the shape of the upper curved portion CV3 (refer to FIG. 8C) in an area overlapping the first portion PT1.

In an embodiment, a lower surface P1B of the first portion PT1 may have a shape corresponding to the upper surface IL41U of the first upper portion and the upper surface IL42U of the second upper portion. That is, in an area where the upper insulating layer INLA has a shape protruded to the third direction DR3, the lower surface P1B of the first portion PT1 may have a shape recessed the third direction DR3.

In an embodiment, the upper surface P1U of the first portion PT1 may be entirely flat. However, the invention should not be limited thereto or thereby. As an example, the upper surface PU of the first portion PT1 may protrude in the third direction DR3 in an area of an upper surface HU of the upper insulating layer INLA which has the shape protruding in the third direction DR3.

In an embodiment, the first portion PT1 may overlap the first upper portion INL4-1 and the second upper portion INL4-2. FIG. 8D shows the structure in which the first portion PT1 overlaps three first upper portions INL4-1 and four second upper portions INL4-2 as a representative example. However, the number of the first upper portions INL4-1 and the number of the second upper portion INL4-2, which overlap the first portion PT1, may be different depending on the number of the driving lines CL overlapping the first portion PT1 and should not be particularly limited.

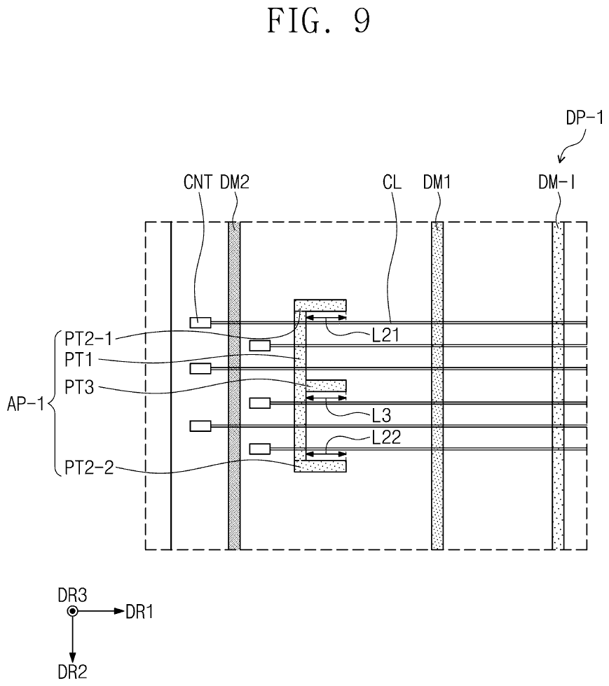

FIGS. 9 to 12 are plan views of shielding portions, according to embodiments.

As an example, FIGS. 9 to 12 are plan views of the shielding portions in an area corresponding to the area AA′ of FIG. 4, according to an embodiment. In FIGS. 9 to 12, the same/similar reference numerals denote the same/similar elements in FIGS. 1A to 8D, and thus, detailed descriptions of the same elements will be omitted.

In an embodiment and referring to FIG. 9, a display panel DP-1 may include a shielding portion AP-1.

In an embodiment, the shielding portion AP-1 may be provided in plural.

At least a portion of the shielding portions AP-1 may include a third portion PT3 that is disposed between a second-first portion PT2-1 and a second-second portion PT2-2, that protrudes from a first portion PT1 in the first direction DR1, and that does not overlap driving lines CL.

A protrusion length in the first direction DR1 of the third portion PT3 may be referred to as a third protrusion length L3. The third protrusion length L3 may be equal to a first protrusion length L21 and a second protrusion length L22, however, the invention should not be limited thereto or thereby. According to another embodiment, the third protrusion length L3 may be different from the first protrusion length L21 or the second protrusion length L22.

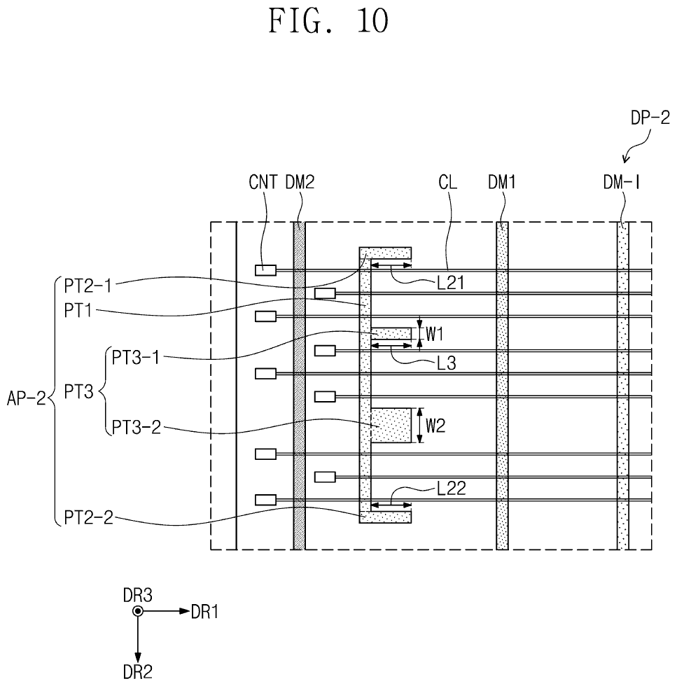

In an embodiment and referring to FIG. 10, a display panel DP-2 may include a shielding portion AP-2.

In an embodiment, the shielding portion AP-2 may be provided in plural. At least a portion of the shielding portions AP-2 may include a third portion PT3 that is disposed between a second-first portion PT2-1 and a second-second portion PT2-2, that protrudes from a first portion PT1 in the first direction DR1, and that does not overlap driving lines CL.

The third portion PT3 may include a third-first portion PT3-1 and a third-second portion PT3-2, however, the invention should not be limited thereto or thereby. As an example, in another embodiment, the third portion PT3 may include only the third-first portion PT3-1 or may include three or more portions.

The third-first portion PT3-1 may have a first width W1 in the second direction DR2, and the third-second portion PT3-2 may have a second width W2 in the second direction DR2. FIG. 10 shows a structure in which the first width W1 is different from the second width W2 as a representative example, however, the invention should not be limited thereto or thereby. According to another embodiment, the first width W1 may be the same as the second width W2.

In an embodiment, a protrusion length directed in first direction DR1 of the third portion PT3 from the first portion PT1, i.e., a third protrusion length L3, may be substantially the same as a first protrusion length L21 and a second protrusion length L22, however, the invention should not be limited thereto or thereby. According to another embodiment, the third protrusion length L3 may be different from the first protrusion length L21 or the second protrusion length L22.

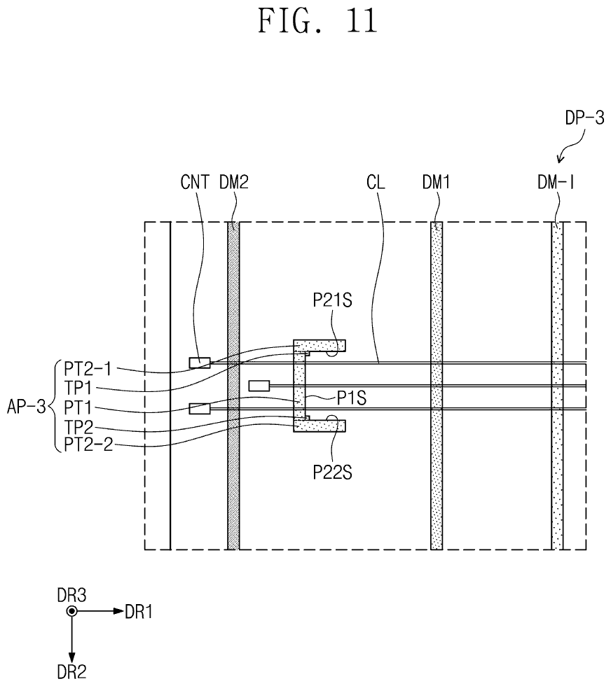

In an embodiment and referring to FIG. 11, a display panel DP-3 may include a shielding portion AP-3.

In an embodiment, the shielding portion AP-3 may be provided in plural.

At least a portion of the shielding portions AP-3 may further include a first tip portion PT1 connected to a surface PIS of a first portion PT1, which faces a first dam DM1, and a surface P21S of a second-first portion PT2-1, which faces a second-second portion PT2-2, and a second tip portion TP2 connected to the surface PIS of the first portion PT1, which faces the first dam DM1, and a surface P22S of the second-second portion PT2-2, which faces the second-first portion PT2-1.

When viewed in a plane, the first tip portion TP1 may have a size smaller than a size of the second-first portion PT2-1, and the second tip portion TP2 may have a size smaller than a size of the second-second portion PT2-2.

Although not shown separately, in an embodiment, the layer structure of the shielding portion AP (refer to FIG. 7) described with reference to FIG. 7 may be equally applied to the first tip portion TP1 and the second tip portion TP2.

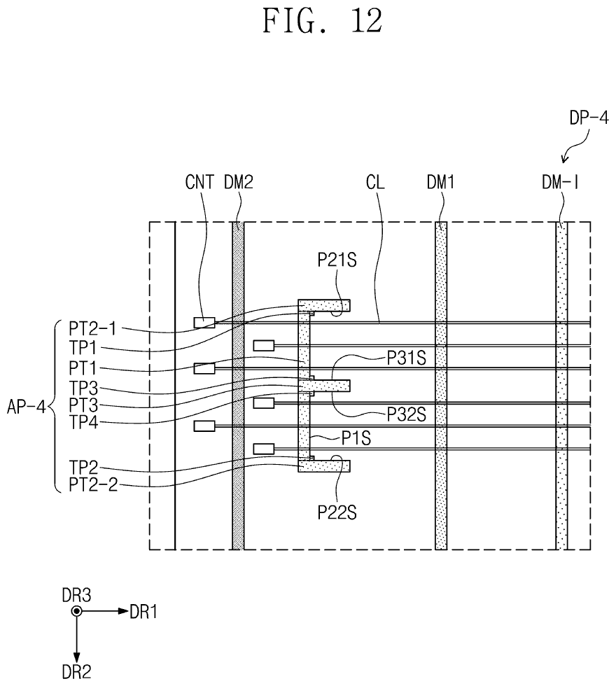

In an embodiment and referring to FIG. 12, a display panel DP-4 may include a shielding portion AP-4.

In an embodiment, the shielding portion AP-4 may be provided in plural.

At least a portion of the shielding portions AP-4 may further include a third portion PT3 that is disposed between a second-first portion PT2-1 and a second-second portion PT2-2, that protrudes from a first portion PT1 to the first direction DR1, and that does not overlap driving lines CL, a first tip portion PT1 connected to a surface PIS of the first portion facing a first dam DM1 and a surface P21S of the second-first portion facing the second-second portion, a second tip portion TP2 connected to the surface PIS of the first portion facing the first dam DM1 and a surface P22S of the second-second portion facing the second-first portion, a third tip portion TP3 connected to the surface PIS of the first portion facing the first dam DM1 and a surface P31S of the third portion facing the second-first portion, and a fourth tip portion TP4 connected to the surface PIS of the first portion facing the first dam DM1 and a surface P32S of the third portion facing the second-second portion.

When viewed in a plane, the first tip portion TP1 may have a size smaller than a size of the second-first portion PT2-2, the second tip portion TP2 may have a size smaller than a size of the second-second portion PT2-2, the third tip portion TP3 may have a size smaller than a size of the third portion PT3, and the fourth tip portion TP4 may have a size smaller than the size of the third portion PT3.

Although not shown separately, in an embodiment, the layer structure of the shielding portion AP (refer to FIG. 7) described with reference to FIG. 7 may be equally applied to the first to fourth tip portions TP1 to TP4.

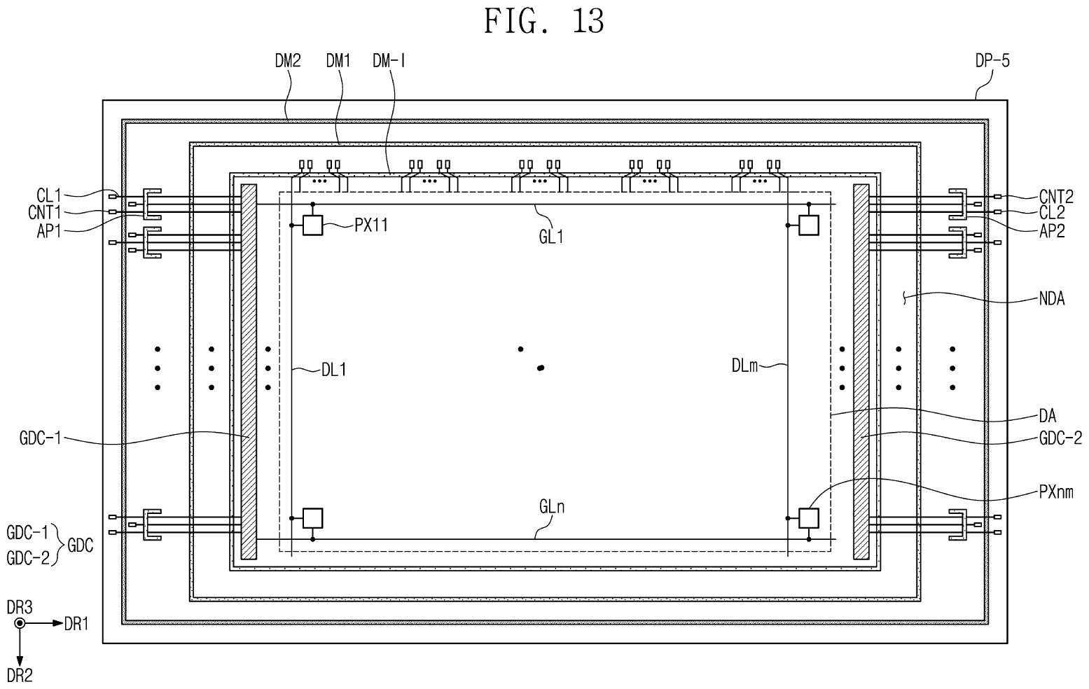

FIG. 13 is a plan view of a display panel DP-5, according to an embodiment.

In an embodiment and referring to FIG. 13, a gate driving circuit GDC may include a first gate driving circuit GDC-1 and a second gate driving circuit GDC-2, which are disposed in a non-display area NDA and which are spaced apart from each other with a display area DA interposed therebetween in the first direction DR1.

The display panel DP-5 may include a first driving line CL1, a first shielding portion AP1 overlapping the first driving line CL1, a second driving line CL2, and a second shielding portion AP2 overlapping the second driving line CL2.

Although embodiments of the invention have been described, it is understood that the invention should not be limited to these embodiments but various changes and modifications can be made by one of ordinary skill in the art within the spirit and scope of the invention. Therefore, the disclosed subject matter should not be limited to any single embodiment described herein or otherwise. Moreover, embodiments or parts of the embodiments may be combined in whole or in part without departing from the scope of the invention.

What is claimed is:

1. A display device comprising:
a display panel; and
a gate driving circuit which outputs a signal to the display panel, the display panel comprising:
pixels;
a base layer comprising a display area and a non-display area disposed adjacent to the display area;
driving lines disposed on the base layer, connected to the gate driving circuit and extending in a first direction;
an upper insulating layer disposed on the base layer;
a first dam disposed on the upper insulating layer and overlapping the non-display area;
a second dam disposed on the upper insulating layer and spaced farther apart from the display area than the first dam is; and
a shielding portion disposed between the first dam and the second dam on the upper insulating layer, the shielding portion comprising:
a first portion overlapping at least one of the driving lines and extending in a second direction intersecting the first direction;
a second-first portion that protrudes from one end of the first portion in the first direction and that does not overlap the driving lines; and
a second-second portion that protrudes from the other end of the first portion in the first direction and that does not overlap the driving lines.

2. The display device of claim 1, wherein the shielding portion includes a plurality of shielding portions that are arranged to be spaced apart from each other in the second direction.

3. The display device of claim 2, wherein at least a portion of the plurality of shielding portions further comprise a third portion that is disposed between the second-first portion and the second-second portion, that protrudes from the first portion in the first direction, and that does not overlap the driving lines.

4. The display device of claim 3, wherein the third portion comprises a third-first portion having a first width in the second direction and a third-second portion having a second width in the second direction.

5. The display device of claim 4, wherein the first width is different from the second width.

6. The display device of claim 1, wherein the display panel further comprises:
a lower insulating layer disposed between the base layer and the driving lines; and
an intermediate insulating layer disposed between the lower insulating layer and the upper insulating layer and covering the driving lines, wherein the upper insulating layer is disposed on the intermediate insulating layer, and wherein a stepped portion is defined between an upper surface of the lower insulating layer and a side surface of each of the driving lines, and due to a thickness of the driving lines, an intermediate curved portion curved corresponding to a shape of the stepped portion is defined in the intermediate insulating layer, and an upper curved portion curved corresponding to a shape of the intermediate insulating layer is defined in the upper insulating layer.

7. The display device of claim 6, wherein the display panel further comprises:
an initial dam disposed on the upper insulating layer to be closer to the display area than the first dam is; and
an encapsulation layer comprising a first inorganic layer disposed on the upper insulating layer and covering the shielding portion, an organic layer that is disposed on the first inorganic layer and that does not overlap the shielding portion, and a second inorganic layer disposed on the organic layer and covering the shielding portion, wherein a boundary of the organic layer is defined by the initial dam, and wherein an inorganic curved portion curved corresponding to a shape of the upper curved portion is defined in the first inorganic layer.

8. The display device of claim 7, wherein the display panel further comprises an over-organic material that is disposed on the first inorganic layer and that is covered by the second inorganic layer, wherein at least a portion of the over-organic material extends in the first direction, and wherein the over-organic material comprises a same material as the organic layer.

9. The display device of claim 1, wherein the display panel further comprises:
an organic insulating layer disposed on the upper insulating layer; and
a pixel definition layer disposed on the organic insulating layer, wherein the shielding portion comprises a first shielding layer comprising a same material as the organic insulating layer and a second shielding layer disposed on the first shielding layer and comprising a same material as the pixel definition layer.

10. The display device of claim 1, wherein the gate driving circuit overlaps the non-display area, and wherein the shielding portion is spaced farther apart from the display area than the gate driving circuit is.

11. The display device of claim 1, wherein a first thickness of the second-first portion in a third direction directed perpendicular to the first and second directions is uniform in the second direction in an area overlapping an upper surface of the second-first portion, and wherein a second thickness of the second-second portion in the third direction is uniform in the second direction in an area overlapping an upper surface of the second-second portion.

12. The display device of claim 1, wherein the second-first portion is protruding from the first portion in the first direction by a first protrusion length, the second-second portion is protruding from the first portion in the first direction by a second protrusion length, wherein the first protrusion length is equal to the second protrusion length.

13. The display device of claim 12, wherein each of the first protrusion length and the second protrusion length is equal to or greater than a value obtained by multiplying a number of the driving lines intersecting the first portion when viewed in a plane by about 1.8 micrometers and equal to or smaller than a value obtained by multiplying the number of the driving lines intersecting the first portion when viewed in the plane by about 2.2 micrometers.

14. The display device of claim 1, wherein the shielding portion further comprises a first tip portion connected to a surface of the first portion, which faces the first dam, and a surface of the second-first portion, which faces the second-second portion, and a second tip portion connected to the surface of the first portion, which faces the first dam, and a surface of the second-second portion, which faces the second-first portion, wherein the first tip portion has a size smaller than a size of the second-first portion when viewed in a plane, and wherein the second tip portion has a size smaller than a size of the second-second portion when viewed in the plane.

15. The display device of claim 14, wherein the shielding portion comprises a third portion that is disposed between the second-first portion and the second-second portion, protruding from the first portion in the first direction, and that does not overlap the driving lines, a third tip portion connected to the surface of the first portion, which faces the first dam, and a surface of the third portion, which faces the second-first portion, and a fourth tip portion connected to the surface of the first portion, which faces the first dam, and a surface of the third portion, which faces the second-second portion, wherein the third tip portion and the fourth tip portion have a size smaller than a size of the third portion when viewed in the plane.

16. The display device of claim 1, wherein the gate driving circuit comprises a first gate driving circuit overlapping the non-display area and a second gate driving circuit overlapping the non-display area and disposed to be spaced apart from the first gate driving circuit with the display area interposed therebetween in the first direction.

17. A display device comprising:
a display panel comprising a base layer comprising a display area and a non-display area disposed adjacent to the display area, a lower insulating layer disposed on the base layer, driving lines disposed on the lower insulating layer and extending in a first direction, an upper insulating layer disposed on the lower insulating layer, and a first dam, a shielding portion, and a second dam, which are arranged to be spaced apart from each other in a direction away from the display area; and
a gate driving circuit overlapping the non-display area and disposed closer to the display area than the first dam is, the upper insulating layer comprising:
a first upper portion that overlaps the driving lines; and
a second upper portion that does not overlap the driving lines, wherein an upper surface of the first upper portion is spaced apart from an upper surface of the lower insulating layer by a first distance, an upper surface of the second upper portion is spaced apart from the upper surface of the lower insulating layer by a second distance which is smaller than the first distance, and the shielding portion comprises a first portion overlapping the first upper portion and the second upper portion, a second-first portion protruding from one end of the first portion toward the display area and overlapping the second upper portion, and a second-second portion protruding from the other end of the first portion toward the display area.

18. The display device of claim 17, wherein the shielding portion further comprises a third portion disposed between the second-first portion and the second-second portion, wherein the third portion protrudes from a surface of the first portion, which faces the first dam, to the display area, and which overlaps the second upper portion.

19. The display device of claim 17, wherein each of a first protrusion length of the second-first portion protruding from the first portion toward the display area and a second protrusion length of the second-second portion protruding from the first portion toward the display area is equal to or greater than a value obtained by multiplying a number of the driving lines overlapping the first portion by about 1.8 micrometers and equal to or smaller than a value obtained by multiplying the number of the driving lines by about 2.2 micrometers.

20. The display device of claim 17, wherein the display panel further comprises an encapsulation layer comprising a first inorganic layer disposed on the upper insulating layer, an organic layer disposed on the first inorganic layer, and a second inorganic layer disposed on the organic layer, wherein the first inorganic layer comprises a first inorganic portion overlapping the first upper portion and a second inorganic portion overlapping the second upper portion.

21. The display device of claim 20, wherein the display panel further comprises an over-organic material disposed on the first inorganic layer, covered by the second inorganic layer, and comprising a same material as the organic layer, wherein a value obtained by multiplying a separation distance between the second-first portion and the second-second portion, one protrusion length that is smaller than the other protrusion length between the first protrusion length of the second-first portion protruded from the first portion toward the display area and the second protrusion length of the second-second portion protruding from the first portion toward the display panel, and a height of the shielding portion is defined as a volume of a barrier space, wherein the volume of the barrier space is equal to or greater than about twelve times and equal to or smaller than about thirty times a volume of the over-organic material disposed between the second-first portion and the second-second portion.
